(19) United States
(12) Patent Application Publication
(10) Pub. No.: US 2024/0419074 A1
(43) Pub. Date: Dec. 19, 2024

(54) FORMATION OF SUB-LITHOGRAPHIC MANDREL PATTERNS USING REVERSIBLE OVERCOAT

(71) Applicant: Tokyo Electron Limited, Tokyo (JP)

(72) Inventors: Michael Murphy, Albany, NY (US); Jacob Dobson, Albany, NY (US); Jodi Grzeskowiak, Albany, NY (US); David Conklin, Saratoga Springs, NY (US)

(21) Appl. No.: 18/615,313

(22) Filed: Mar. 25, 2024

Related U.S. Application Data
(60) Provisional application No. 63/472,910, filed on Jun. 14, 2023.

(51) Int. Cl. G03F 7/11; G03F 7/004; G03F 7/20

(52) U.S. Cl. CPC G03F 7/11; G03F 7/0045; G03F 7/2026

(57) ABSTRACT

A method includes forming a plurality of first mandrels over a substrate, forming an overcoat layer over the plurality of first mandrels, and inducing a crosslinking reaction within the overcoat layer and form a crosslinked overcoat layer. The method further includes exposing the substrate to a radiation to generate a plurality of acid molecules within the plurality of first mandrels, diffusing a portion of the plurality of acid molecules from the plurality of first mandrels into portions of the crosslinked overcoat layer, and inducing a decrosslinking reaction within the portions of the crosslinked overcoat layer and form de-crosslinked regions. Unmodified regions of the crosslinked overcoat layer form a plurality of second mandrels. The method further includes selectively removing the de-crosslinked regions. The plurality of first mandrels and the plurality of second mandrels form a mandrel pattern over the substrate.

### CROSS-REFERENCE TO RELATED APPLICATIONS

This application claims the benefit of U.S. Provisional Application No. 63/472,910, filed on Jun. 14, 2023, which application is hereby incorporated herein by reference.

### TECHNICAL FIELD

The present disclosure relates generally to methods for processing a substrate and, in particular embodiments, to methods for formation of sub-lithographic mandrel patterns over a substrate using a reversible overcoat.

### BACKGROUND

In material processing methodologies (such as photolithography), creating patterned layers typically involves the application of a thin layer of radiation-sensitive material, such as photoresist, to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system. This exposure creates a latent pattern within the radiation-sensitive material which can then be developed. Developing refers to dissolving and removing a portion of the radiation-sensitive material to yield a relief pattern (topographic pattern). The portion of material removed can be either irradiated regions or non-irradiated regions of the radiation-sensitive material depending on a photoresist tone and/or a type of a developing solvent used. The relief pattern can then function as a mask layer defining a pattern.

Preparation and development of various films used for patterning can include thermal treatment or baking. For example, a newly applied film can receive a post-application bake (PAB) to evaporate solvents and/or to increase structural rigidity or etch resistance. Also, a post-exposure bake (PEB) can be executed to set a given pattern to prevent further dissolving. Fabrication tools for coating and developing substrates typically include one or more baking modules. Some photolithography processes include coating a substrate with a thin film of Bottom Anti-reflective Coating (BARC), followed by coating with a photoresist, and then exposing the substrate to a pattern of light as a process step for creating microchips. A relief pattern created in the photoresist can then be used as a mask or template for additional processing such as transferring the pattern into an underlying layer, such as the thin film of BARC.

### SUMMARY

In accordance with an embodiment of the present disclosure, a method includes forming a plurality of first mandrels over a substrate, forming an overcoat layer over the plurality of first mandrels, and inducing a crosslinking reaction within the overcoat layer and form a crosslinked overcoat layer. The method further includes exposing the substrate to a radiation to generate a plurality of acid molecules within the plurality of first mandrels, diffusing a portion of the plurality of acid molecules from the plurality of first mandrels into portions of the crosslinked overcoat layer, and inducing a decrosslinking reaction within the portions of the crosslinked overcoat layer and form de-crosslinked regions. Unmodified regions of the crosslinked overcoat layer form a plurality of second mandrels. The method further includes selectively removing the de-crosslinked regions. The plurality of first mandrels and the plurality of second mandrels form a mandrel pattern over the substrate.

In accordance with an embodiment of the present disclosure, a method includes forming a plurality of first mandrels over a substrate. The plurality of first mandrels have a first solubility in a first developer. The method further includes forming an overcoat layer over the plurality of first mandrels. The overcoat layer has a second solubility in the first developer. The method further includes exposing the substrate to a radiation to generate a plurality of acid molecules within the plurality of first mandrels. The method further includes baking the substrate to diffuse a portion of the plurality of acid molecules from the plurality of first mandrels into portions of the overcoat layer, and induce a reaction within the portions of the overcoat layer to increase a solubility of the portions of the overcoat layer in the first developer to a third solubility greater than the first solubility and the second solubility. Unmodified regions of the overcoat layer form a plurality of second mandrels. The method further includes developing the substrate in the first developer. The first developer dissolves the portions of the overcoat layer. The plurality of first mandrels and the plurality of second mandrels form a mandrel pattern over the substrate.

In accordance with an embodiment of the present disclosure, a method includes forming a first mandrel and a second mandrel over a substrate. The first mandrel is spaced apart from the second mandrel. The method further includes forming an overcoat layer over the first mandrel and the second mandrel and baking the substrate to induce a crosslinking reaction within the overcoat layer and form a crosslinked overcoat layer. The method further includes exposing the first mandrel to a first dose of a radiation to generate a first plurality of acid molecules within the first mandrel and exposing the second mandrel to a second dose of the radiation to generate a second plurality of acid molecules within the second mandrel. The first dose of the radiation is different from the second dose of the radiation. The method further includes baking the substrate to diffuse a portion of the first plurality of acid molecules into a first portion of the crosslinked overcoat layer to a first depth and diffuse a portion of the second plurality of acid molecules into a second portion of the crosslinked overcoat layer to a second depth. The second depth is different from the first depth. The method further includes baking the substrate to induce a de-crosslinking reaction within the first portion of the crosslinked overcoat layer to form a first de-crosslinked region. The first de-crosslinked region extends along a top and sidewalls of the first mandrel. The method further includes baking the substrate to induce a decrosslinking reaction within the second portion of the crosslinked overcoat layer to form a second de-crosslinked region. The second de-crosslinked region extends along a top and sidewalls of the second mandrel. An unmodified region of the crosslinked overcoat layer interposed between the first de-crosslinked region and the second de-crosslinked region forms a third mandrel. The method further includes selectively removing the first de-crosslinked region and the second de-crosslinked region. The first mandrel, the second mandrel, and the third mandrel form a mandrel pattern on the substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1I illustrate cross-sectional views of different stages of a method for forming a mandrel pattern in accordance with various embodiments;

FIGS. 2A and 2B illustrate cross-sectional views of different stages of a method for forming a mandrel pattern in accordance with various embodiments;

FIGS. 3A-3C illustrate cross-sectional views of different stages of a method for forming a mandrel pattern in accordance with various embodiments;

FIGS. 4A and 4B illustrate cross-sectional views of different stages of a method for forming a mandrel pattern in accordance with various embodiments; and

FIG. 5 illustrates a flow diagram of a method for forming a mandrel pattern in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Ever continuous scaling of various features of microchips requires improved patterning resolution. One approach is spacer technology to define sub-resolution line features via an ALD (atomic layer deposition) process. One challenge, however, is that if the opposite tone feature is desired, using spacer techniques can be complex involving over-coating another material, chemical mechanical planarization (CMP), and reactive ion etch (RIE) to exhume the spacer material leaving a narrow trench, which can be costly.

Anti-spacer technology is a self-aligned technology that uses the diffusion length of a reactive species (e.g., acid) to define a critical dimension (CD), creating a narrow trench. With a reactive species controlled spatially via exposure through a reticle, then instead of a narrow trench, a narrow slot contact can be formed. A corresponding CD can be tuned through molecular weight modification of the reactive species, molecular structures of the reactive species, and a bake temperature and a bake duration. These techniques enable access to narrow slot contact features at dimensions beyond the reach of advanced lithographic capabilities.

Anti-spacer formation is a means to achieve self-aligned double patterning (SADP) through spin-on processes, thereby improving throughput and overall cost. Additionally, limitations of conventional SADP processes, such as resolving a single thickness across a wafer, can be overcome with anti-spacer processes. As features are formed through diffusion of a solubility changing species across an interface the formation of the solubility changing species can be modulated across the wafer to enable multiple feature widths in a single process.

The density of the final pattern, however, is limited within anti-spacer flows exhibiting change in critical dimension (CD) of a single mandrel, this is particularly apparent when the final target pitch is approaching one half the resolution limit of the lithographic exposure. To achieve a 1:1 line-space (L/S) mandrel pattern (e.g., equal pitch between mandrels), the initial lithographic exposure is biased to account for the addition of a mandrel or anti-spacer and achieve the target pitch.

When the target pitch is approaching a half of the resolution limit of the lithographic exposure the correct bias is no longer resolvable and additional post-exposure processes must be employed. Resolution limitation of the employed lithographic technology prevents desired biasing of the incoming L/S pattern to enable symmetrical L/S patterning, which results in asymmetrical L/S patterning post multi-patterning processing.

The acid-in anti-spacer process is pitch limited due to unidirectional CD change by diffusion of an acid into first mandrels. A width of the patterned trenches between the first mandrels post-lithography becomes the final width of the second mandrels post-anti-spacer process. Accordingly, widths of the second mandrels are limit by the photolithography process.

Techniques described in this disclosure provide a reversible overcoat to achieve sub-lithographic mandrel patterns. Disclosed techniques include an anti-spacer patterning scheme that relies on diffusion of a solubility-changing species outward from the photoresist mandrels into the reversible overcoat to cause a reaction resulting in the formation of narrow trenches. The disclosed process flow overcomes the pitch limitation of an acid-in unidirectional diffusion process flow using a post-lithographic trim of the photoresist mandrels to resolve the required bias of the line-space pattern to achieve a final symmetrical mandrel pattern.

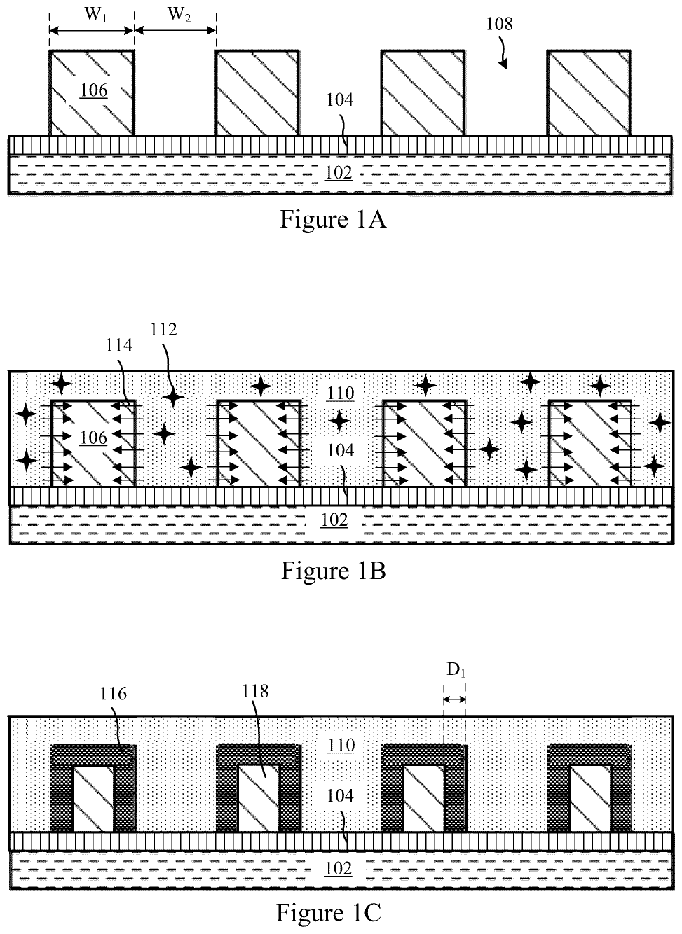

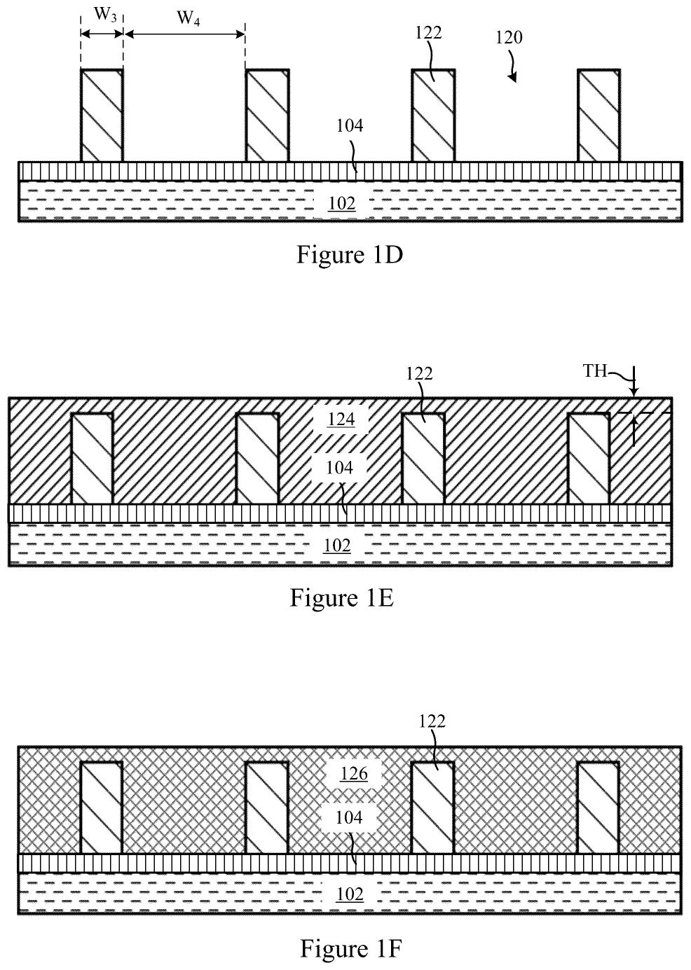

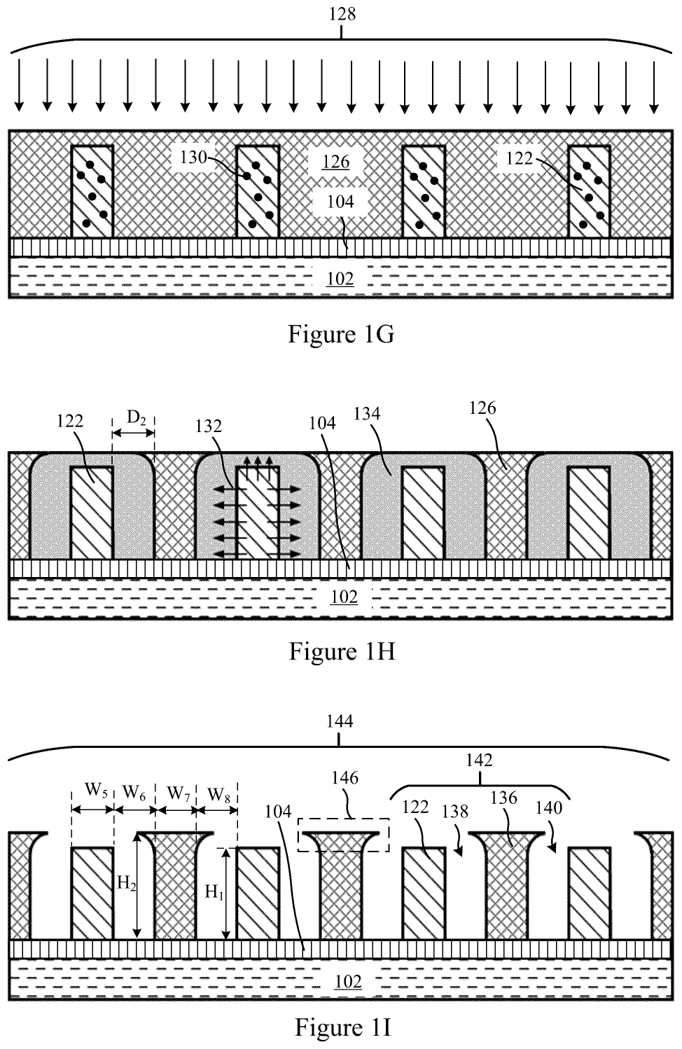

FIGS. 1A-1I illustrate cross-sectional views of different stages of a method for forming a mandrel pattern 144 over a substrate 102 in accordance with various embodiments. Referring to FIG. 1A, a plurality of mandrels 106 are formed over the substrate 102. The substrate 102 may be a part of, or include, a semiconductor device or a semiconductor structure, and may be formed in any suitable manner, including using any suitable combination of wet and/or dry deposition, photolithography and etch techniques. For example, the semiconductor structure may comprise the substrate 102 in which various device regions are formed. In such embodiments, the substrate 102 may include isolation regions such as shallow trench isolation (STI) regions, diffusion regions, as well as other regions formed therein.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device or the semiconductor structure.

Referring further to FIG. 1A, in some embodiments, an intermediate layer 104 is formed over the substrate 102 such that the mandrels 106 are formed over the intermediate layer 104. The intermediate layer 104 may be a target for pattern transfer in subsequent processing after the formation the mandrel pattern 144 (see FIG. 11) is completed. The intermediate layer 104 may comprise silicon, silicon oxynitride, organic material, non-organic material, amorphous carbon, or the like. The intermediate layer 104 may be selected to have anti-reflective properties such as by using a silicon bottom anti-reflective coating (Si-BARC), for example. The intermediate layer 104 may be a mask layer comprising a hard mask. Further, the intermediate layer 104 may be a stacked hard mask comprising, for example, two or more layers of two or more different materials. In embodiments when the hard mask comprises two layers, a first layer of the hard mask may comprise a metal-based layer such as titanium nitride, titanium, tantalum nitride, tantalum, tungsten-based compounds, ruthenium-based compounds, or aluminum-based compounds, and a second layer of the hard mask may comprise a dielectric layer such as silicon dioxide, silicon nitride, silicon oxynitride, silicon carbide, amorphous silicon, or polycrystalline silicon. The intermediate layer 104 may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other layer deposition processes or combinations of processes.

In some embodiments, the mandrels 106 may be formed by forming a photoresist layer (not shown) over the intermediate layer 104 and patterning the photoresist layer using suitable photolithographic techniques. The photoresist layer may comprise a positive-tone photoresist or a negative-tone photoresist. In the illustrated embodiment, the photoresist layer comprises a positive-tone chemically amplified photoresist (CAR). The photoresist layer may be deposited on the substrate 102 in any suitable manner. For example, the photoresist layer may be deposited by spin-coating, spray-coating, dip-coating, or roll-coating. As a particular example, the photoresist layer may be deposited on the substrate 102 using a spin-on deposition technique, which may be also referred to as spin-coating. In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

With spin-on deposition, a particular material (e.g., a material of the photoresist layer) is deposited on the substrate 102 (e.g., on the intermediate layer 104 formed on the substrate 102). The substrate 102 is then rotated (if not already rotating, possibly at a relatively low velocity) at a relatively high velocity so that centrifugal force causes the deposited material to move toward edges of the substrate 102, thereby coating the substrate 102. Excess material is typically spun off the substrate 102. In certain embodiments, the spin-on deposition technique includes dispensing liquid chemicals onto the substrate 102 (e.g., on a top surface of the intermediate layer 104) using a coating module with a liquid delivery system that may dispense one or more types of liquid chemicals. The dispense volume can be in a range from 0.2 ml to 10 ml, for example, in a range from 0.5 ml to 2 ml. The substrate 102 may be secured to a rotating chuck that supports the substrate 102. The rotating speed during the liquid dispense can be in a range from 50 rpm to 3000 rpm, for example, in a range from 1000 rpm to 2000 rpm. The system may also include an anneal module that may bake or apply light radiation to the substrate 102 after the chemicals have been dispensed. It should be understood that this example spin-on deposition technique and associated values are provided as examples only. In other embodiments, the photoresist layer may be deposited using a CVD process, a plasma-enhanced CVD process, an ALD process, or other suitable processes.

After forming the photoresist layer, a reticle (not shown) is disposed over the photoresist layer. The reticle may be used to modulate a dose (or an intensity) of a radiation (e.g., actinic radiation) that is used to expose the photoresist layer. In such embodiments, the reticle may comprise regions of different transparency to the radiation (e.g., opaque and transparent regions). The photoresist layer is then subject to an exposure step through the reticle. The radiation exposes exposed regions of the photoresist layer while unexposed (or unmodified) regions of the photoresist layer are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates an acid in the exposed regions of the photoresist layer. The acid may be generated from the PAG that is present in the photoresist layer under the influence of the radiation. The acid may react with the material of the photoresist layer and alter the solubility of the exposed regions of the photoresist layer. Subsequently, the exposed regions of the photoresist layer are removed by performing a developing process using a suitable developer. The developing process forms a plurality of openings 108 in the photoresist layer that expose portions of the intermediate layer 104. The unexposed regions of the photoresist layer form the plurality of mandrels 106.

The mandrels 106 may have a width W₁ and the openings 108 may have a width W₂. The width W₁ may be in a range from 37 nm to 150 nm for 193i lithographic materials and process. The width W₁ may be in a range from 13 nm to 36 nm for EUV lithographic materials and process. The width W₂ may be in a range from 37 nm to 150 nm for 193i lithographic materials and process. The width W₂ may be in a range from 13 nm to 36 nm for EUV lithographic materials and process. In some embodiments, the width W₁ and/or the width W₂ may have smallest values that are achievable by photolithographic techniques. In the illustrated embodiment, a ratio W₁: W₂ equals 1:1. In other embodiments, the ratio W₁: W₂ may be in a range from 1:1 to 5:1.

Referring to FIG. 1B, an overcoat layer 110 is deposited over the substrate 102 in any suitable manner. For example, the overcoat layer 110 may be deposited by spin-coating, spray-coating, dip-coating, or roll-coating. As a particular example, the overcoat layer 110 may be deposited on the substrate 102 using a spin-on deposition technique, which may be also referred to as spin-coating. The spin-on deposition technique has been described above with reference to FIG. 1A and the description is not repeated herein. The overcoat layer 110 may be also referred to as a trim layer. The overcoat layer 110 may fill the openings 108 (see FIG. 1A) and cover top surfaces of the mandrels 106.

A material for the overcoat layer 110 may be chosen such that the overcoat layer 110 could be removed in a subsequent developing process as described below in greater detail. In some embodiment, the overcoat layer 110 may be a multicomponent material that, as deposited, includes a first component and a second component. The first component could be, for example, a polymer. The second component could be, for example, a solubility-changing agent 112, such as an acid (e.g., a free acid). In the illustrated embodiment, the solubility-changing agent 112 comprises a plurality of acid molecules that are depicted as filled 4-point stars in FIG. 1B. The second component could be, as another example, an agent-generating ingredient that, in response to a suitable agent-activation trigger (e.g., heat or radiation), generates a solubility-changing agent (e.g., an acid). Example agent-generating ingredients may include a TAG that is configured to generate an acid in response to heat or a PAG that is configured to generate an acid in response to actinic radiation.

For example, in the case of the overcoat layer 110 including a free acid, a solubility-changing agent 112 may be the free acid and subsequent baking of the substrate 102 may cause the free acid to diffuse (as indicated by arrows 114) into perimeter portions of the mandrels 106 and cause the perimeter portions of the mandrels 106 to become soluble in a developer.

As another example, in the case of the overcoat layer 110 including a TAG as an agent-generating ingredient, subsequent baking of the substrate 102 may cause the TAG to generate a solubility-changing agent 112 (e.g., acid), which may be referred to as activating the acid, cause the generated solubility-changing agent 112 to diffuse (as indicated by arrows 114) into perimeter portions of the mandrels 106, and cause the perimeter portions of the mandrels 106 to become soluble in a developer.

As another example, in the case of the overcoat layer 110 including a PAG as an agent-generating ingredient, an exposure step that includes exposing the overcoat layer 110 to a radiation (e.g., actinic radiation) may be performed prior to baking the substrate 102. The exposure step may cause the PAG to generate a solubility-changing agent 112 (e.g., acid), which may be referred to as activating the acid. Baking of the substrate 102 may cause the generated solubility-changing agent 112 to diffuse (as indicated by arrows 114) into perimeter portions of the mandrels 106 and cause the perimeter portions of the mandrels 106 to become soluble in a developer.

Referring to FIG. 1C, a baking process is performed on the substrate 102. In certain embodiments, the baking process may be a thermal process that is performed by heating the substrate 102 in a process chamber to a temperature between 50° C. and 250° C., for example, between 60° C. and 140° C. in certain embodiments, in vacuum or under a gas flow. In a particular example, the substrate 102 is baked for a duration in a range from 1 to 3 minutes. The bake conditions may be selected to promote the diffusion of the solubility-changing agent 112 (and possibly generation of the solubility-changing agent 112 from an agent-generating ingredient of the overcoat layer 110, if applicable) and associated change in solubility of the perimeter regions of the mandrels 106 (see FIG. 1B) to a target depth D₁. The depth D₁ may be tuned by parameters of the baking process (such as, for example, a bake temperature and a bake duration) and material parameters (such as, for example, a polymer composition of the mandrels 106, and an acid composition and an acid concentration in the overcoat layer 110). In some embodiments, the depth D₁ may be in a range from 3 nm to 25 nm. In other embodiments, the baking process may be performed in any suitable manner.

In some embodiments, the solubility-changing agent 112 (see FIG. 1B) chemically reacts with a material of the mandrels 106 (see FIG. 1B) to form modified regions 116 of the mandrels 106. The chemical reaction changes the solubility of the modified regions 116 of the mandrels 106 so that the modified regions 116 of the mandrels 106 can be removed in a subsequent developing process. Each modified region 116 extends along sidewalls and a top surface of an unmodified region 118 of a respective mandrel 106 (see FIG. 1B).

Referring to FIG. 1D, a developing process is performed on the substrate 102 using a suitable developer. In various embodiments, the developer may comprise a metal ion free (MIF) developer, for example, an aqueous solution of tetramethylammonium hydroxide (TMAH). In other embodiments, the developer solution may comprise a metal ion containing developer, for example, an aqueous solution of sodium hydroxide (NaOH) or potassium hydroxide (KOH). In some embodiments, the developing process may comprise dipping or soaking the substrate 102 in the developer.

In some embodiments, the developer removes the overcoat layer 110 (see FIG. 1C) and the modified regions 116 (see FIG. 1C), and forms openings 120 that expose the intermediate layer 104. Remaining unmodified regions 118 (see FIG. 1C) of the mandrels 106 form a plurality of mandrels 122 over the intermediate layer 104. The mandrels 122 may have a width W₃ and the openings 120 may have a width W₄. The width W₃ of the mandrels 122 is less than the width W₁ of the mandrels 106 (see FIG. 1A). In some embodiments when than the width W₁ has the smallest value achievable by the photolithography process, the mandrels 122 have a sub-lithographic width. The width W₄ of the openings 120 is greater than the width W₂ of the openings 108 (see FIG. 1A). The width W₃ may be in a range from 20 nm to 120 nm for 193i line-space patterning. The width W₄ may be in a range from 38 nm to 150 nm for 193i line-space patterning. In the illustrated embodiment, a ratio W₃:W₄ equals 1:3. Such a pattern of the mandrels 122 may be also referred to as a 1:3 line-space (L/S) pattern. In other embodiments, a ratio W₃:W₄ may be in a range from 1:1 to 1:4.

Referring to FIG. 1E, an overcoat layer 124 is deposited over the substrate 102 in any suitable manner. For example, the overcoat layer 124 may be deposited by spin-coating, spray-coating, dip-coating, or roll-coating. As a particular example, the overcoat layer 124 may be deposited on the substrate 102 using a spin-on deposition technique, which may be also referred to as spin-coating. The spin-on deposition technique has been described above with reference to FIG. 1A and the description is not repeated herein. The overcoat layer 124 may be also referred to as a reversible overcoat (ROC) layer. The overcoat layer 124 may fill the openings 120 (see FIG. 1D) and cover top surfaces of the mandrels 122. The overcoat layer 124 may have a thickness TH over the top surfaces of the mandrels 122. The thickness TH may be in a range from 1 nm to 50 nm.

A material of the overcoat layer 124 may be selected not to intermix with a material of the mandrels 122. The material of the overcoat layer 124 may comprise various components including a polymer, a cross-linking agent, and a catalyst. The polymer may be a multifunctional polymer resin comprising a moiety capable of reacting with a cross-linking agent to create an acetal bond. Such moieties may comprise a hydroxyl or carboxylic acid functional group (e.g., poly-hydroxystyrene or methacrylic acid, respectively).

The cross-linking agent can have a function of reacting with the polymer to promote hardening of the composition of the overcoat layer 124. The cross-linking agent may include a multifunctional crosslinker comprising between two and four vinyloxy functional groups per molecule of the polymer to enable formation of an insoluble network via the formation of acetal bonds between the cross-linking agent and the polymer. In other embodiments, the cross-linking agent may include N-methoxymethylamide. In some embodiments when the cross-linking agent comprises at least one vinyloxy group as a reactive group, the vinyloxy group enables crosslinking with carboxyl groups and/or phenolic hydroxyl groups contained in the polymer. In such embodiments, the vinyloxy group forms an acetal bond with a carboxyl group or a phenolic hydroxyl group contained in the polymer. In some embodiments, the acetal bond is cleaved by an acid formed from a PAG, or by moisture in air or in a developing solution.

The catalyst may function to decrease an activation energy to initiate crosslinking (e.g., lower bake temperature and/or reduce bake time). The catalyst may include a sulfonic acid such as 4-methylbenzenesulfonic acid, dodecylbenzenesulfonic acid, a combination thereof, a mixture thereof, or the like. In some embodiments, the catalyst may be omitted.

Referring to FIG. 1F, after depositing the overcoat layer 124 (see FIG. 1E), a baking process is performed on the substrate 102 to induce crosslinking within the overcoat layer 124, thereby making the crosslinked overcoat layer 126 insoluble in a subsequently used developer. In certain embodiments, the baking process may be a thermal process that is performed by heating the substrate 102 in a process chamber to a temperature between 80° C. and 160° C., in vacuum or under a gas flow. In a particular example, the substrate 102 is baked for a duration in a range from 1 min to 20 min.

Referring to FIG. 1G, agent-generating ingredients within the mandrels 122 are decomposed to generate a solubility-changing agent 130 (e.g., free acid). In the illustrated embodiment, the solubility-changing agent 130 comprises a plurality of acid molecules that are depicted as filled circles in FIG. 1G. In some embodiments when the agent-generating ingredients comprise a PAG, the solubility-changing agent 130 (e.g., free acid) is generated in response to exposing the mandrels 122 to a radiation 128 (e.g., actinic radiation). In some embodiments, the substrate 102 is flood exposed to the radiation 128. In such embodiments, each mandrel 122 comprises a substantially same amount of the solubility-changing agent 130 (e.g., free acid).

Referring to FIG. 1H, a baking process is performed on the substrate 102. The baking process diffuses (as indicated by arrows 132) the solubility-changing agent 130 (see FIG. 1G) out of the mandrels 122, across interfaces between the mandrels 122 and the crosslinked overcoat layer 126 and into the crosslinked overcoat layer 126 causing decrosslinking reactions within the crosslinked overcoat layer 126 to a target depth D₂ to form de-crosslinked regions 134. The de-crosslinked regions 134 may be also referred to as anti-spacers. In certain embodiments, the baking process may be a thermal process that is performed by heating the substrate 102 in a process chamber to a temperature between 60° C. and 120° C., in vacuum or under a gas flow. In a particular example, the substrate 102 is baked for a duration in a range from 0.5 min to 5 min.

The depth D₂ may be tuned by parameters of the baking process (such as, for example, a bake temperature and a bake duration) and material parameters (such as, for example, a polymer composition of the crosslinked overcoat layer 126, and an acid composition and an acid concentration in the mandrels 122). The depth D₂ may be in a range from 5 nm to 50 nm. In some embodiments, the depth D₂ and the thickness TH of the overcoat layer 124 (see FIG. 1E) may be tuned such that the depth D₂ is greater than the thickness TH. In such embodiments, the solubility-changing agent 130 (see FIG. 1G) diffuses (as indicated by arrows 132) from the top surfaces of the mandrels 122 to a top surface of the crosslinked overcoat layer 126, such that top surfaces of the de-crosslinked regions 134 are exposed and are level with a top surface of the crosslinked overcoat layer 126.

Referring to FIG. 1I, a developing process is performed on the substrate 102 using a suitable developer. The suitable developer may comprise an organic solvent that is selective to the de-crosslinked regions 134 (see FIG. 1H). In some embodiments, a solubility of the de-crosslinked regions 134 in the suitable developer is greater than a solubility of the crosslinked overcoat layer 126 in the suitable developer and a solubility of the mandrels 122 in the suitable developer. The developing process selectively removes the de-crosslinked regions 134 to form openings 138 and 140 that expose the intermediate layer 104. Remaining regions of the crosslinked overcoat layer 126 form a plurality of mandrels 136. The mandrels 122 and 136 form a mandrel pattern 144 on the substrate 102. In some embodiments, the mandrels 122 have a height H₁ and the mandrels 136 have a height H₂, with the height H₂ being greater than the height H₁. The height H₁ may be in a range from 50 nm to 150 nm for 193i photoresists. The height H₂ may be in a range from 50 nm to 150 nm when the overcoat layer 124 (see FIG. 1E) is coated overtop 193i photoresists. In some embodiments, a width of the mandrels 136 increases as the mandrels 136 extend away from the substrate 102. In such embodiments, the mandrels 136 comprise overhang regions 146 that overhang the openings 138 and 140.

In some embodiments, the mandrel pattern 144 comprises a plurality of mandrel patterns 142. Each mandrel pattern 142 comprises mandrels 122 and 136, and openings 138 and 140, with the opening 138 being interposed between the mandrel 122 and the mandrel 136, and the mandrel 136 being interposed between the opening 138 and the opening 140. The mandrel 122 may have a width W₅, the mandrel 136 may have a width W₇, the opening 138 may have a width W₆, and the opening 140 may have a width W₈. The width W₅ may be in a range from 15 nm to 30 nm. The width W₆ may be in a range from 15 nm to 30 nm. The width W₇ may be in a range from 15 nm to 30 nm. The width W₈ may be in a range from 15 nm to 30 nm. In the illustrated embodiment, a ratio W₅:W₆:W₇:W₈ equals 1:1:1:1. In such embodiments, the mandrel pattern 144may be also referred to as a 1:1:1:1 L/S pattern. In other embodiments, the ratio W₅:W₆:W₇:W₈ may be equal to 1:X:(3-2X):X, where X is the depth D₂ as measured in units of the width W_{5,} with X being in a range from 0 to 3/2. In some embodiments, the pattern of the mandrel pattern 144 may be tuned by tuning X (i.e., by tuning the depth D₂). In an example when X=1 (i.e., when D₂=W₅), the mandrel pattern 144 is the 1:1:1:1 L/S pattern.

In some embodiments, a pattern of the mandrel pattern 144 is transferred into the intermediate layer 104. For example, the intermediate layer 104 may be etched by an anisotropic etching process, such as reactive ion etch (RIE), while using the mandrel pattern 144 as an etch mask. In various embodiments, the transferred pattern may be used to form a contact hole, a via, a metal line, gate line, isolation region, and other features useful in semiconductor fabrication.

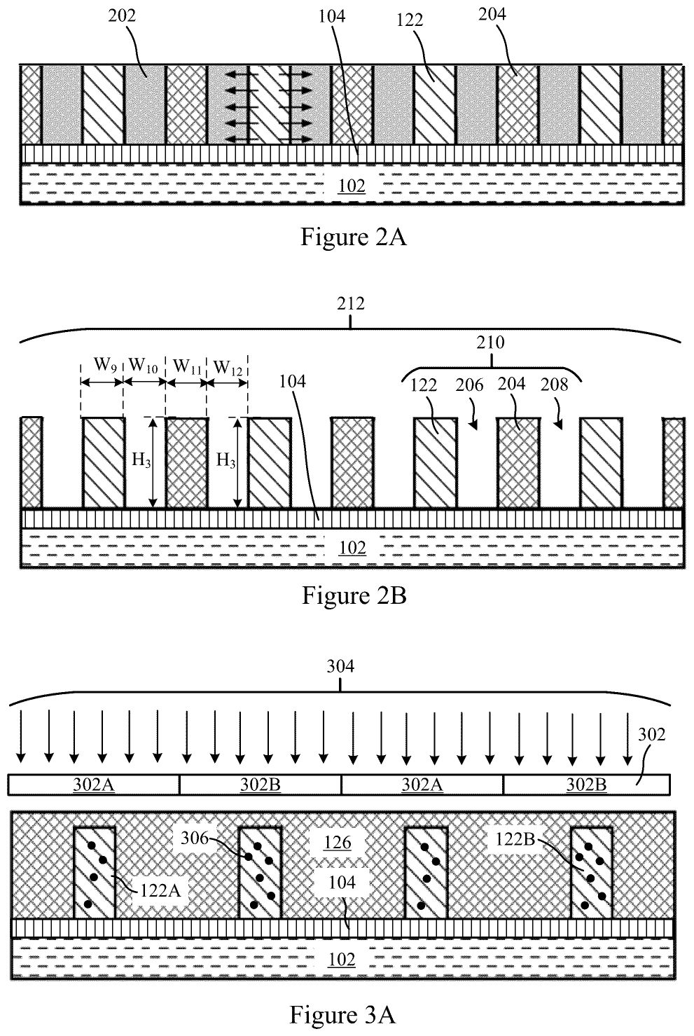

FIGS. 2A and 2B illustrate cross-sectional views of different stages of a method for forming a mandrel pattern 212 over a substrate 102 in accordance with various embodiments. Referring to FIG. 2A, after forming a structure as illustrated in FIG. 1H, the crosslinked overcoat layer 126 and the de-crosslinked regions 134 are recessed to expose the mandrels 122. In some embodiments, the recessing process may comprise a suitable etch process, such as an anisotropic dry etch process, for example. Remaining portions of the de-crosslinked regions 134 form de-crosslinked regions 202 and remaining portions of the crosslinked overcoat layer 126 form a plurality of mandrels 204. In some embodiments, top surfaces of the mandrels 122 are level with top surfaces of the mandrels 204. The de-crosslinked regions 202 may be also referred to as anti-spacers.

Referring to FIG. 2B, a developing process is performed on the substrate 102 using a suitable developer. The suitable developer may comprise an organic solvent that is selective to the de-crosslinked regions 202 (see FIG. 2A). In some embodiments, a solubility of the de-crosslinked regions 202 in the suitable developer is greater than a solubility of the mandrels 122 and 204 in the suitable developer. The developing process selectively removes the de-crosslinked regions 202 to form openings 206 and 208 that expose the intermediate layer 104. The mandrels 122 and 204 form a mandrel pattern 212 on the substrate 102. In some embodiments, the mandrels 122 and 204 have a height H₃. The height H₃ may be in a range from 30 nm to 120 nm.

In some embodiments, the mandrel pattern 212 comprises a plurality of mandrel patterns 210. Each mandrel pattern 210 comprises mandrels 122 and 204, and openings 206 and 208, with the opening 206 being interposed between the mandrel 122 and the mandrel 204, and the mandrel 204 being interposed between the opening 206 and the opening 208. The mandrel 122 may have a width W₉, the mandrel 204 may have a width W₁₁, the opening 206 may have a width W₁₀, and the opening 208 may have a width W₁₂. The width W₉ may be in a range from 15 nm to 30 nm. The width W₁₀ may be in a range from 15 nm to 30 nm. The width W₁₁ may be in a range from 15 nm to 30 nm. The width W₁₂ may be in a range from 15 nm to 30 nm. In the illustrated embodiment, a ratio W₉:W₁₀:W₁₁:W₁₂ equals 1:1:1:1. In such embodiments, the mandrel pattern 212 may be also referred to as a 1:1:1:1 L/S pattern. In other embodiments, the ratio W₉:W₁₀:W₁₁:W₁₂ may be equal to 1:Y:(3-2Y):Y, where Y is the depth D₂ as measured in units of the width W₉, with Y being in a range from 0 to 3/2. In some embodiments, the pattern of the mandrel pattern 212 may be tuned by tuning Y (i.e., by tuning the depth D₂). In an example when Y=1 (i.e., when D₂₌W₉), the mandrel pattern 212 is the 1:1:1:1 L/S pattern.

In some embodiments, a pattern of the mandrel pattern 212 is transferred into the intermediate layer 104. For example, the intermediate layer 104 may be etched by an anisotropic etching process, such as reactive ion etch (RIE), while using the mandrel pattern 212 as an etch mask. In various embodiments, the transferred pattern may be used to form a contact hole, a via, a metal line, gate line, isolation region, and other features useful in semiconductor fabrication.

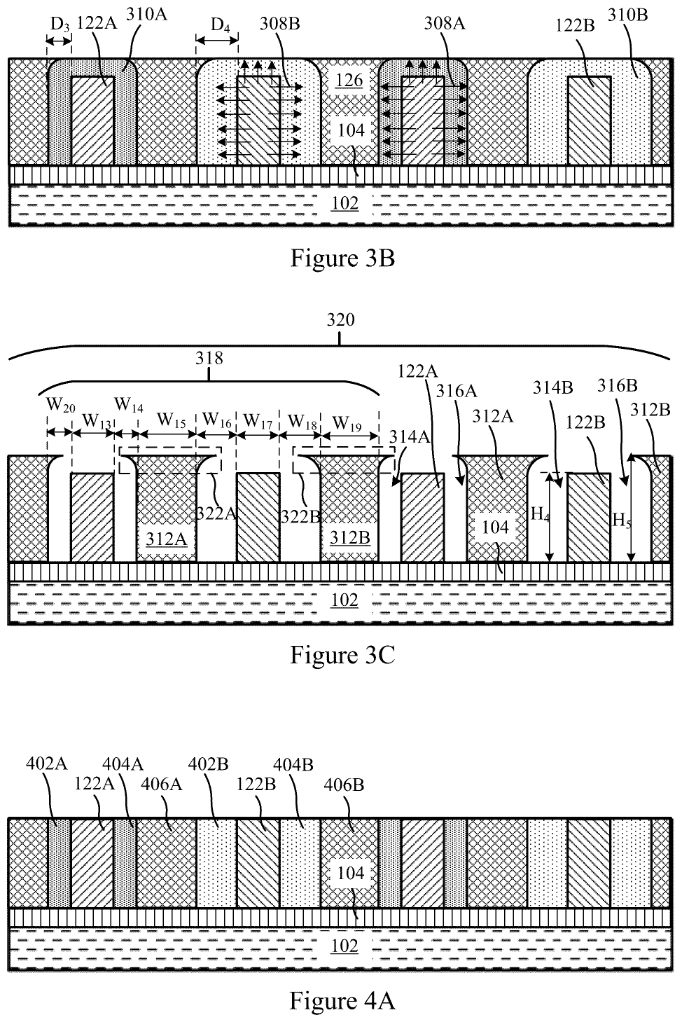

FIGS. 3A-3C illustrate cross-sectional views of different stages of a method for forming a mandrel pattern 320 over a substrate 102 in accordance with various embodiments. Referring to FIG. 3A, after forming a structure as illustrated in Figure IF, agent-generating ingredients within the mandrels 122 are decomposed to generate a solubility-changing agent 306 (e.g., free acid). In the illustrated embodiment, the solubility-changing agent 306 comprises a plurality of acid molecules that are depicted as filled circles in FIG. 3A. In some embodiments when the agent-generating ingredients comprise a PAG, the solubility-changing agent 306 (e.g., free acid) is generated in response to exposing the mandrels 122 to a radiation 304 (e.g., actinic radiation). In some embodiments, the substrate 102 is exposed to the radiation 128 through a reticle 302. In such embodiments, the reticle 302 is disposed over the substrate 102. The reticle 302 may be used to modulate a dose (or an intensity) of a radiation (e.g., actinic radiation) that is used to expose the substrate 102. In such embodiments, the reticle 302 may comprise regions 302A and 302B of different transparency to the radiation 304. In the illustrated embodiment, regions 302B have a greater transparency than regions 302A to the radiation 304. Due to the difference in transparencies, mandrels 122A that are disposed below the regions 302A of the reticle 302 have less amount (or concentration) of the solubility-changing agent 130 (e.g., free acid) than mandrels 122B that are disposed below the regions 302B of the reticle 302.

Referring to FIG. 3B, a baking process is performed on the substrate 102. The baking process diffuses (as indicated by arrows 308A) the solubility-changing agent 306 (see FIG. 3A) out of the mandrels 122A, across interfaces between the mandrels 122A and the crosslinked overcoat layer 126 and into the crosslinked overcoat layer 126 causing decrosslinking reactions within the crosslinked overcoat layer 126 to a target depth D₃ to form de-crosslinked regions 310A. The baking process further diffuses (as indicated by arrows 308B) the solubility-changing agent 306 (see FIG. 3A) out of the mandrels 122B, across interfaces between the mandrels 122B and the crosslinked overcoat layer 126 and into the crosslinked overcoat layer 126 causing decrosslinking reactions within the crosslinked overcoat layer 126 to a target depth D₄ to form de-crosslinked regions 310B. The de-crosslinked regions 310A and 310B may be also referred to as anti-spacers. In certain embodiments, the baking process may be a thermal process that is performed by heating the substrate 102 in a process chamber to a temperature between 60° C. and 120° C., in vacuum or under a gas flow. In a particular example, the substrate 102 is baked for a duration in a range from 0.5 min to 5 min.

The depth D₃ may be tuned by parameters of the baking process (such as, for example, a bake temperature and a bake duration) and material parameters (such as, for example, a polymer composition of the crosslinked overcoat layer 126, and an acid composition and an acid concentration in the mandrels 122A). The depth D₃ may be in a range from 5 nm to 45 nm. The depth D₄ may be tuned by parameters of the baking process (such as, for example, a bake temperature and a bake duration) and material parameters (such as, for example, a polymer composition of the crosslinked overcoat layer 126, and an acid composition and an acid concentration in the mandrels 122B). The depth D₄ may be in a range from 5 nm to 45 nm.

In the illustrated embodiment, due to difference in amount of the solubility-changing agent 306 in the mandrels 122A and 122B, the depth D₃ is less than the depth D₄. In some embodiments, the depth D₃, the depth D₄, and the thickness TH of the overcoat layer 124 (see FIG. 1E) may be tuned such that a lesser of the depths D₃ and D₄ is greater than the thickness TH. In such embodiments, the solubility-changing agent 306 (see FIG. 3A) diffuses (as indicated by arrows 308A) from the top surfaces of the mandrels 122A to a top surface of the crosslinked overcoat layer 126, such that top surfaces of the de-crosslinked regions 310A are exposed and are level with a top surface of the crosslinked overcoat layer 126. Furthermore, the solubility-changing agent 306 (see FIG. 3A) diffuses (as indicated by arrows 308B) from the top surfaces of the mandrels 122B to the top surface of the crosslinked overcoat layer 126, such that top surfaces of the de-crosslinked regions 310B are exposed and are level with the top surface of the crosslinked overcoat layer 126.

Referring to FIG. 3C, a developing process is performed on the substrate 102 using a suitable developer. The suitable developer may comprise an organic solvent that is selective to the de-crosslinked regions 310A and 310B (see FIG. 3B). In some embodiments, a solubility of the de-crosslinked regions 310A and 310B in the suitable developer is greater than a solubility of the crosslinked overcoat layer 126 in the suitable developer and a solubility of the mandrels 122A and 122B in the suitable developer. The developing process selectively removes the de-crosslinked regions 310A to form openings 314A and 316A that expose the intermediate layer 104. The developing process further selectively removes the de-crosslinked regions 310B to form openings 314B and 316B that expose the intermediate layer 104.

Remaining regions of the crosslinked overcoat layer 126 form a plurality of mandrels 312A and 312B. A mandrel 312A is interposed between an opening 316A and an opening 314B. A mandrel 312B is interposed between an opening 316B and an opening 314A. The mandrels 122A, 122B, 312A, and 312B form a mandrel pattern 320 on the substrate 102. In some embodiments, the mandrels 122A and 122B have a height H₄ and the mandrels 312A and 312B have a height H₅, with the height Hs being greater than the height H₄. The height H₄ may be in a range from 30 nm to 120 nm. The height H₅ may be in a range from 30 nm to 120 nm. In some embodiments, a width of the mandrels 312A increases as the mandrels 312A extend away from the substrate 102 and a width of the mandrels 312B increases as the mandrels 312B extend away from the substrate 102. In such embodiments, the mandrels 312A comprise overhang regions 322A that overhang the openings 316A and 314B, and the mandrels 312B comprise overhang regions 322B that overhang the openings 316B and 314A.

In some embodiments, the mandrel pattern 320 comprises a plurality of mandrel patterns 318. Each mandrel pattern 318 comprises mandrels 122A, 122B, 312A, and 312B, and openings 314A, 316A, 314B, and 316B, with the opening 316A being interposed between the mandrels 122A and 312A, the mandrel 312A being interposed between the openings 316A and 314B, the opening 314B being interposed the mandrels 312A and 122B, the mandrel 122B being interposed between the openings 314B and 316B, the opening 316B being interposed between the mandrels 122B and 312B, and the mandrel 312B being interposed between the opening 316B and 314A. The mandrel 122A may have a width W₁₃, the mandrel 122B may have a width W₁₇, the mandrel 312A may have a width W₁₅, the mandrel 312B may have a width W₁₉, the opening 316A may have a width W₁₄, the opening 314B may have a width W₁₆, the opening 316B may have a width W₁₈, and the opening 314A may have a width W₂₀.

The width W₁₃ may be in a range from 15 nm to 30 nm. The width W₁₄ may be in a range from 15 nm to 30 nm. The width W₁₅ may be in a range from 15 nm to 30 nm. The width W₁₆ may be in a range from 15 nm to 30 nm. The width W₁₇ may be in a range from 15 nm to 30 nm. The width W₁₈ may be in a range from 15 nm to 30 nm. The width W₁₉ may be in a range from 15 nm to 30 nm. The width W₂₀ may be in a range from 15 nm to 30 nm. In some embodiments, the ratio W₁₃:W₁₄:W₁₅:W₁₆:W₁₇:W₁₈:W₁₉:W20 may be equal to 1:X1:(3-X1-X2):X2:1:X2:(3-X1-X2):X1, where X1 is the depth D₃ (see FIG. 3B) as measured in units of the width W₁₃ (or the width W₁₇) and X2 is the depth D₄ (see FIG. 3B) as measured in units of the width W₁₃ (or the width W₁₇), with X1+X2 being in a range from 0 to 3. In some embodiments, the pattern of the mandrel pattern 320 may be tuned by tuning X1 (i.e., by tuning the depth D₃) and/or X2 (i.e., by tuning the depth D₄). In an example when X1=1 (i.e., when D₃=W₁₃=W₁₇) and X2=1 (i.e., when D₄=W₁₃=W₁₇), the mandrel pattern 320 is the 1:1:1:1:1:1:1:1 L/S pattern.

In some embodiments, a pattern of the mandrel pattern 320 is transferred into the intermediate layer 104. For example, the intermediate layer 104 may be etched by an anisotropic etching process, such as reactive ion etch (RIE), while using the mandrel pattern 320 as an etch mask. In various embodiments, the transferred pattern may be used to form a contact hole, a via, a metal line, gate line, isolation region, and other features useful in semiconductor fabrication.

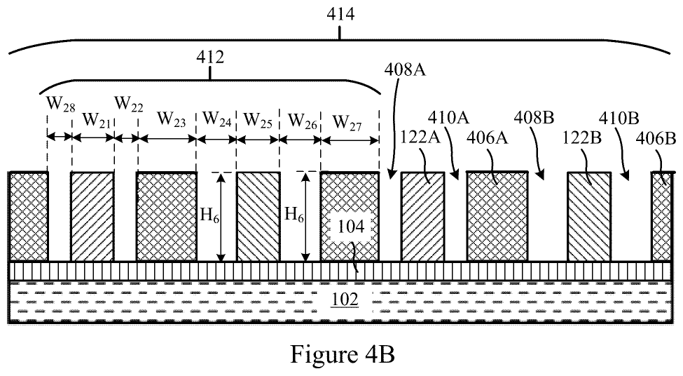

FIGS. 4A and 4B illustrate cross-sectional views of different stages of a method for forming a mandrel pattern 414 over a substrate 102 in accordance with various embodiments. Referring to FIG. 4A, after forming a structure as illustrated in FIG. 3B, the crosslinked overcoat layer 126 and the de-crosslinked regions 310A and 310B are recessed to expose the mandrels 122A and 122B. In some embodiments, the recessing process may comprise a suitable etch process, such as an anisotropic dry etch process, for example. Remaining portions of the de-crosslinked regions 310A (see FIG. 3B) form de-crosslinked regions 402A and 404A, remaining portions of the de-crosslinked regions 310B (see FIG. 3B) form de-crosslinked regions 402B and 404B, remaining portions of the crosslinked overcoat layer 126 form a plurality of mandrels 406A and a plurality of mandrels 406B. In some embodiments, top surfaces of the mandrels 122A and 122B are level with top surfaces of the mandrels 406A and top surfaces of the mandrels 406B. The de-crosslinked regions 402A, 404A, 402B, and 404B may be also referred to as anti-spacers.

Referring to FIG. 4B, a developing process is performed on the substrate 102 using a suitable developer. The suitable developer may comprise an organic solvent that is selective to the de-crosslinked regions 402A, 404A, 402B, and 404B (see FIG. 4A). In some embodiments, a solubility of the de-crosslinked regions 402A, 404A, 402B, and 404B in the suitable developer is greater than a solubility of the mandrels 122A, 122B, 406A, and 406B in the suitable developer. The developing process selectively removes the de-crosslinked regions 402A to form openings 408A that expose the intermediate layer 104. The developing process selectively removes the de-crosslinked regions 404A to form openings 410A that expose the intermediate layer 104. The developing process selectively removes the de-crosslinked regions 402B to form openings 408B that expose the intermediate layer 104. The developing process selectively removes the de-crosslinked regions 404B to form openings 410B that expose the intermediate layer 104. The mandrels 122A, 122B, 406A, and 406B form a mandrel pattern 414 on the substrate 102. In some embodiments, the mandrels 122A, 122B, 406A, and 406B have a height H₆. The height H₆ may be in a range from 30 nm to 120 nm.

In some embodiments, the mandrel pattern 414 comprises a plurality of mandrel patterns 412. Each mandrel pattern 412 comprises mandrels 122A, 122B, 406A, and 406B, and openings 408A, 410A, 408B, and 410B, with the opening 410A being interposed between the mandrels 122A and 406A, the mandrel 406A being interposed between the openings 410A and 408B, the opening 408B being interposed the mandrels 406A and 122B, the mandrel 122B being interposed between the openings 408B and 410B, the opening 410B being interposed between the mandrels 122B and 406B, and the mandrel 406B being interposed between the opening 410B and 408A. The mandrel 122A may have a width W₂₁, the mandrel 122B may have a width W₂₅, the mandrel 406A may have a width W₂₃, the mandrel 406B may have a width W₂₇, the opening 410A may have a width W₂₂, the opening 408B may have a width W₂₄, the opening 410B may have a width W₂₆, and the opening 408A may have a width W₂₈.

The width W₂₁ may be in a range from 15 nm to 30 nm. The width W₂₂ may be in a range from 15 nm to 30 nm. The width W₂₃ may be in a range from 15 nm to 30 nm. The width W₂₄ may be in a range from 15 nm to 30 nm. The width W₂₅ may be in a range from 15 nm to 30 nm. The width W₂₆ may be in a range from 15 nm to 30 nm. The width W₂₇ may be in a range from 15 nm to 30 nm. The width W₂₈ may be in a range from 15 nm to 30 nm. In some embodiments, the ratio W₂₁:W₂₂:W₂₃:W₂₄:W₂₅:W₂₆:W₂₇:W₂₈ may be equal to 1:Y1:(3-Y1-Y2):Y2:1:Y2:(3-Y1-Y2):Y1, where Y1 is the depth D₃ (see FIG. 3B) as measured in units of the width W₂₁ (or the width W₂₅) and Y2 is the depth D₄ (see FIG. 3B) as measured in units of the width W₂₁ (or the width W₂₅), with Y1+Y2 being in a range from 0 to 3. In some embodiments, the pattern of the mandrel pattern 414 may be tuned by tuning Y1 (i.e., by tuning the depth D₃) and/or Y2 (i.e., by tuning the depth D₄). In an example when Y1=1 (i.e., when D₃=W₂₁=W₂₅) and Y2=1 (i.e., when D₄₌W21=W25), the mandrel pattern 414 is the 1:1:1:1:1:1:1:1 L/S pattern.

In some embodiments, a pattern of the mandrel pattern 414 is transferred into the intermediate layer 104. For example, the intermediate layer 104 may be etched by an anisotropic etching process, such as reactive ion etch (RIE), while using the mandrel pattern 414 as an etch mask. In various embodiments, the transferred pattern may be used to form a contact hole, a via, a metal line, gate line, isolation region, and other features useful in semiconductor fabrication.

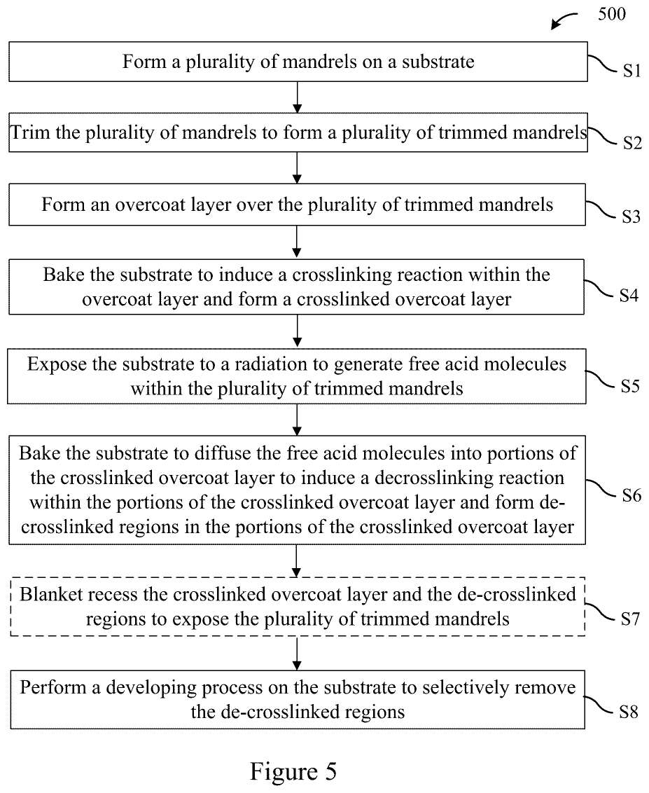

FIG. 5 illustrates a flow diagram of a method 500 for forming a mandrel pattern in accordance with various embodiments. In one embodiment, the mandrel pattern formed the method 500 may be the mandrel pattern 144 of FIG. 1I. In another embodiment, the mandrel pattern formed the method 500 may be the mandrel pattern 212 of FIG. 2B. In yet another embodiment, the mandrel pattern formed the method 500 may be the mandrel pattern 320 of FIG. 3C. In yet another embodiment, the mandrel pattern formed the method 500 may be the mandrel pattern 414 of FIG. 4B.

Method 500 starts with step S1. In step S1, a plurality of mandrels (e.g., mandrels 106 of FIG. 1A) are formed on a substrate (e.g., substrate 102 of FIG. 1A) as described above with reference to FIG. 1A. In step S2, the plurality of mandrels (e.g., mandrels 106 of FIG. 1A) are trimmed to from a plurality of trimmed mandrels (e.g., mandrels 122 of FIG. 1D) as described above with reference to FIGS. 1B-1D. In step S3, an overcoat layer (e.g., overcoat layer 124 of FIG. 1E) is formed over the plurality of trimmed mandrels (e.g., mandrels 122 of FIG. 1E) as described above with reference to FIG. 1E. In step S4, the substrate (e.g., substrate 102 of FIG. 1F) is baked to induce a crosslinking reaction within the overcoat layer (e.g., overcoat layer 124 of FIG. 1E) and form a crosslinked overcoat layer (e.g., crosslinked overcoat layer 126 of FIG. 1F) as described above with reference to FIG. 1F.

In step S5, the substrate is exposed to a radiation to generate free acid molecules within the plurality of trimmed mandrels. In some embodiments, the substrate (e.g., substrate 102 of FIG. 1G) is flood exposed to the radiation (e.g., radiation 128 of FIG. 1G) to generate free acid molecules (e.g., solubility-changing agent 130 of FIG. 1G) within the plurality of trimmed mandrels (e.g., mandrels 122 of FIG. 1G) as described above with reference to FIG. 1G. In other embodiments, the substrate (e.g., substrate 102 of FIG. 3A) is exposed to the radiation (e.g., radiation 304 of FIG. 3A) through a reticle (e.g., reticle 302 of FIG. 3A) to generate free acid molecules (e.g., solubility-changing agent 306 of FIG. 3A) within the plurality of trimmed mandrels (e.g., mandrels 122A and 122B of FIG. 3A) as described above with reference to FIG. 3A.

In step S6, the substrate is baked to diffuse the free acid molecules into portions of the crosslinked overcoat layer to induce a decrosslinking reaction within the portions of the crosslinked overcoat layer and form de-crosslinked regions in the portions of the crosslinked overcoat layer. In some embodiments when the substrate (e.g., substrate 102 of FIG. 1G) is flood exposed to the radiation (e.g., radiation 128 of FIG. 1G), the free acid molecules (e.g., solubility- changing agent 130 of FIG. 1G) diffuse into portions of the crosslinked overcoat layer (e.g., crosslinked overcoat layer 126 of FIG. 1G) to induce a decrosslinking reaction within the portions of the crosslinked overcoat layer (e.g., crosslinked overcoat layer 126 of FIG. 1G) and form de-crosslinked regions (e.g., de-crosslinked regions 134 of FIG. 1H) in the portions of the crosslinked overcoat layer (e.g., crosslinked overcoat layer 126 of FIG. 1G) as described above with reference to FIG. 1H.

In some embodiments when the substrate (e.g., substrate 102 of FIG. 3A) is exposed to the radiation (e.g., radiation 304 of FIG. 3A) through the reticle (e.g., reticle 302 of FIG. 3A), the free acid molecules (e.g., solubility-changing agent 306 of FIG. 3A) diffuse into portions of the crosslinked overcoat layer (e.g., crosslinked overcoat layer 126 of FIG. 3A) to induce a decrosslinking reaction within the portions of the crosslinked overcoat layer (e.g., crosslinked overcoat layer 126 of FIG. 3A) and form de-crosslinked regions (e.g., de-crosslinked regions 310A and 310B of FIG. 3B) in the portions of the crosslinked overcoat layer (e.g., crosslinked overcoat layer 126 of FIG. 3A) as described above with reference to FIG. 3B.

In step S7, in some embodiments, the crosslinked overcoat layer and the de-crosslinked regions are blanket recessed to expose the plurality of trimmed mandrels. In some embodiments when the substrate (e.g., substrate 102 of FIG. 1G) is flood exposed to the radiation (e.g., radiation 128 of FIG. 1G), the crosslinked overcoat layer (e.g., crosslinked overcoat layer 126 of FIG. 1H) and the de-crosslinked regions (e.g., de-crosslinked regions 134 of FIG. 1H) are blanket recessed to expose the plurality of trimmed mandrels (e.g., mandrels 122 of FIG. 2A) as described above with reference to FIG. 2A.

In some embodiments when the substrate (e.g., substrate 102 of FIG. 3A) is exposed to the radiation (e.g., radiation 304 of FIG. 3A) through the reticle (e.g., reticle 302 of FIG. 3A), the crosslinked overcoat layer (e.g., crosslinked overcoat layer 126 of FIG. 3B) and the de-crosslinked regions (e.g., de-crosslinked regions 310A and 310B of FIG. 3B) are blanket recessed to expose the plurality of trimmed mandrels (e.g., mandrels 122A and 122B of FIG. 4A) as described above with reference to FIG. 4A. In other embodiments, step S7 may be omitted.

In step S8, a developing process is performed on the substrate to selectively remove the de-crosslinked regions, such that remaining mandrels form a mandrel pattern. In some embodiments when step S7 is omitted and the substrate (e.g., substrate 102 of FIG. 1G) is flood exposed to the radiation (e.g., radiation 128 of FIG. 1G), a developing process is performed on the substrate (e.g., substrate 102 of FIG. 1H) to selectively remove the de-crosslinked regions (e.g., de-crosslinked regions 134 of FIG. 1H), such that remaining mandrels (e.g., mandrels 122 and 136 of FIG. 11) form a mandrel pattern (e.g., mandrel pattern 144 of FIG. 1I) as described above with reference to FIG. 1I.

In some embodiments when step S7 is performed and the substrate (e.g., substrate 102 of FIG. 1G) is flood exposed to the radiation (e.g., radiation 128 of FIG. 1G), a developing process is performed on the substrate (e.g., substrate 102 of FIG. 2A) to selectively remove the de-crosslinked regions (e.g., de-crosslinked regions 202 of FIG. 2A), such that remaining mandrels (e.g., mandrels 122 and 204 of FIG. 2B) form a mandrel pattern (e.g., mandrel pattern 212 of FIG. 2B) as described above with reference to FIG. 2B.

In some embodiments when step S7 is omitted and the substrate (e.g., substrate 102 of FIG. 3A) is exposed to the radiation (e.g., radiation 304 of FIG. 3A) through the reticle (e.g., reticle 302 of FIG. 3A), a developing process is performed on the substrate (e.g., substrate 102 of FIG. 3B) to selectively remove the de-crosslinked regions (e.g., de-crosslinked regions 310A and 310B of FIG. 3B), such that remaining mandrels (e.g., mandrels 122A, 122B, 312A, and 312B of FIG. 3C) form a mandrel pattern (e.g., mandrel pattern 320 of FIG. 3C) as described above with reference to FIG. 3C.

In some embodiments when step S7 is performed and the substrate (e.g., substrate 102 of FIG. 3A) is exposed to the radiation (e.g., radiation 304 of FIG. 3A) through the reticle (e.g., reticle 302 of FIG. 3A), a developing process is performed on the substrate (e.g., substrate 102 of FIG. 4A) to selectively remove the de-crosslinked regions (e.g., de-crosslinked regions 402A, 404A, 402B, and 404B of FIG. 4A), such that remaining mandrels (e.g., mandrels 122A, 122B, 406A, and 406B of FIG. 4B) form a mandrel pattern (e.g., mandrel pattern 414 of FIG. 4B) as described above with reference to FIG. 4B.

Embodiments described herein may achieve various advantages. By forming a reversible overcoat layer over mandrels such that a thickness of the reversible overcoat layer over top surfaces of the mandrels is maintained to be less than a diffusion distance of an acid from the mandrels, anti-spacers that are formed in the reversible overcoat layer will be exposed though a remaining portion of the reversible overcoat layer such that the anti-spacers are efficiently removed in a subsequent developing step. Various embodiments allow for tuning a diffusion of the acid into the reversible overcoat layer by tuning process parameters (such as, for example, a bake temperature and a bake duration) and/or material parameters (such as, for example, a polymer composition of the reversible overcoat layer, and an acid composition and an acid concentration in the mandrels). As the widths of the ant-spacers are defined by the acid diffusion, widths of openings formed after removing the anti-spacers can also be tuned by tuning process parameters (such as, for example, a bake temperature and a bake duration) and/or material parameters (such as, for example, a polymer composition of the reversible overcoat layer, and an acid composition and an acid concentration in the mandrels). By exposing different mandrels to different radiation doses (e.g., using a reticle), openings of different widths may be formed in a single process.

Example embodiments of the disclosure are described below. Other embodiments can also be understood from the entirety of the specification as well as the claims filed herein.

Example 1. A method includes forming a plurality of first mandrels over a substrate, forming an overcoat layer over the plurality of first mandrels, and inducing a crosslinking reaction within the overcoat layer and form a crosslinked overcoat layer. The method further includes exposing the substrate to a radiation to generate a plurality of acid molecules within the plurality of first mandrels, diffusing a portion of the plurality of acid molecules from the plurality of first mandrels into portions of the crosslinked overcoat layer, and inducing a decrosslinking reaction within the portions of the crosslinked overcoat layer and form de-crosslinked regions. Unmodified regions of the crosslinked overcoat layer form a plurality of second mandrels. The method further includes selectively removing the de-crosslinked regions. The plurality of first mandrels and the plurality of second mandrels form a mandrel pattern over the substrate.

Example 2. The method of example 1, further including, before selectively removing the de-crosslinked regions, blanket recessing the crosslinked overcoat layer and the de-crosslinked regions to expose the plurality of first mandrels.

Example 3. The method of one of examples 1 and 2, where the plurality of first mandrels and the plurality of second mandrels have a same height.

Example 4. The method of one of examples 1 to 3, where widths of the plurality of second mandrels increase as the plurality of second mandrels extend away from the substrate.

Example 5. The method of one of examples 1 to 4, where a height of the plurality of first mandrels is less than a height of the plurality of second mandrels.

Example 6. The method of one of examples 1 to 5, where the plurality of first mandrels, the plurality of second mandrels, and the de-crosslinked regions have a same width.

Example 7. The method of one of examples 1 to 6, where the plurality of first mandrels include a same amount of acid molecules.

Example 8. A method includes forming a plurality of first mandrels over a substrate. The plurality of first mandrels have a first solubility in a first developer. The method further includes forming an overcoat layer over the plurality of first mandrels. The overcoat layer has a second solubility in the first developer. The method further includes exposing the substrate to a radiation to generate a plurality of acid molecules within the plurality of first mandrels. The method further includes baking the substrate to diffuse a portion of the plurality of acid molecules from the plurality of first mandrels into portions of the overcoat layer, and induce a reaction within the portions of the overcoat layer to increase a solubility of the portions of the overcoat layer in the first developer to a third solubility greater than the first solubility and the second solubility. Unmodified regions of the overcoat layer form a plurality of second mandrels. The method further includes developing the substrate in the first developer. The first developer dissolves the portions of the overcoat layer. The plurality of first mandrels and the plurality of second mandrels form a mandrel pattern over the substrate.

Example 9. The method of example 8, where the reaction is a decrosslinking reaction.

Example 10. The method of one of examples 8 and 9, further including, before developing the substrate, exposing top surfaces of the plurality of first mandrels.

Example 11. The method of one of examples 8 to 10, where the substrate is flood exposed to the radiation.

Example 12. The method of one of examples 8 to 11, where the substrate is exposed to the radiation through a reticle.

Example 13. The method of one of examples 8 to 12, where the plurality of first mandrels include different amounts of acid molecules.

Example 14. The method of one of examples 8 to 13, where a top surface of the overcoat layer above top surfaces of the plurality of first mandrels.

Example 15. A method includes forming a first mandrel and a second mandrel over a substrate. The first mandrel is spaced apart from the second mandrel. The method further includes forming an overcoat layer over the first mandrel and the second mandrel and baking the substrate to induce a crosslinking reaction within the overcoat layer and form a crosslinked overcoat layer. The method further includes exposing the first mandrel to a first dose of a radiation to generate a first plurality of acid molecules within the first mandrel and exposing the second mandrel to a second dose of the radiation to generate a second plurality of acid molecules within the second mandrel. The first dose of the radiation is different from the second dose of the radiation. The method further includes baking the substrate to diffuse a portion of the first plurality of acid molecules into a first portion of the crosslinked overcoat layer to a first depth and diffuse a portion of the second plurality of acid molecules into a second portion of the crosslinked overcoat layer to a second depth. The second depth is different from the first depth. The method further includes baking the substrate to induce a de-crosslinking reaction within the first portion of the crosslinked overcoat layer to form a first de-crosslinked region. The first de-crosslinked region extends along a top and sidewalls of the first mandrel. The method further includes baking the substrate to induce a decrosslinking reaction within the second portion of the crosslinked overcoat layer to form a second de-crosslinked region. The second de-crosslinked region extends along a top and sidewalls of the second mandrel. An unmodified region of the crosslinked overcoat layer interposed between the first de-crosslinked region and the second de-crosslinked region forms a third mandrel. The method further includes selectively removing the first de-crosslinked region and the second de-crosslinked region. The first mandrel, the second mandrel, and the third mandrel form a mandrel pattern on the substrate.

Example 16. The method of example 15, where a width of the first de-crosslinked region is different from a width of the second de-crosslinked region.

Example 17. The method of one of examples 15 and 16, where a width of the first mandrel is different from a width of the third mandrel.

Example 18. The method of one of examples 15 to 17, where a height of the first mandrel is different from a height of the third mandrel.

Example 19. The method of one of examples 15 to 18, where the third mandrel includes an overhang region.

Example 20. The method of one of examples 15 to 19, where the overcoat layer has a first thickness over a top surface the first mandrel and a top surface of the second mandrel, and where the first thickness is less than a lesser of the first depth and the second depth.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming a plurality of first mandrels over a substrate;
forming an overcoat layer over the plurality of first mandrels;
inducing a crosslinking reaction within the overcoat layer and form a crosslinked overcoat layer;
exposing the substrate to a radiation to generate a plurality of acid molecules within the plurality of first mandrels;
diffusing a portion of the plurality of acid molecules from the plurality of first mandrels into portions of the crosslinked overcoat layer;
inducing a decrosslinking reaction within the portions of the crosslinked overcoat layer and form de-crosslinked regions, wherein unmodified regions of the crosslinked overcoat layer form a plurality of second mandrels; and
selectively removing the de-crosslinked regions, wherein the plurality of first mandrels and the plurality of second mandrels form a mandrel pattern over the substrate.

2. The method of claim 1, further comprising:
before selectively removing the de-crosslinked regions, blanket recessing the crosslinked overcoat layer and the de-crosslinked regions to expose the plurality of first mandrels.

3. The method of claim 2, wherein the plurality of first mandrels and the plurality of second mandrels have a same height.

4. The method of claim 1, wherein widths of the plurality of second mandrels increase as the plurality of second mandrels extend away from the substrate.

5. The method of claim 1, wherein a height of the plurality of first mandrels is less than a height of the plurality of second mandrels.

6. The method of claim 1, wherein the plurality of first mandrels, the plurality of second mandrels, and the de-crosslinked regions have a same width.

7. The method of claim 1, wherein the plurality of first mandrels comprise a same amount of acid molecules.

8. A method comprising:
forming a plurality of first mandrels over a substrate, the plurality of first mandrels having a first solubility in a first developer;
forming an overcoat layer over the plurality of first mandrels, the overcoat layer having a second solubility in the first developer;
exposing the substrate to a radiation to generate a plurality of acid molecules within the plurality of first mandrels;
baking the substrate to:
diffuse a portion of the plurality of acid molecules from the plurality of first mandrels into portions of the overcoat layer; and
induce a reaction within the portions of the overcoat layer to increase a solubility of the portions of the overcoat layer in the first developer to a third solubility greater than the first solubility and the second solubility, wherein unmodified regions of the overcoat layer form a plurality of second mandrels; and
developing the substrate in the first developer, the first developer dissolving the portions of the overcoat layer, wherein the plurality of first mandrels and the plurality of second mandrels form a mandrel pattern over the substrate.

9. The method of claim 8, wherein the reaction is a decrosslinking reaction.

10. The method of claim 8, further comprising, before developing the substrate, exposing top surfaces of the plurality of first mandrels.

11. The method of claim 8, wherein the substrate is flood exposed to the radiation.

12. The method of claim 8, wherein the substrate is exposed to the radiation through a reticle.

13. The method of claim 8, wherein the plurality of first mandrels comprise different amounts of acid molecules.

14. The method of claim 8, wherein a top surface of the overcoat layer above top surfaces of the plurality of first mandrels.

15. A method comprising:
forming a first mandrel and a second mandrel over a substrate, wherein the first mandrel is spaced apart from the second mandrel;
forming an overcoat layer over the first mandrel and the second mandrel;
baking the substrate to induce a crosslinking reaction within the overcoat layer and form a crosslinked overcoat layer;
exposing the first mandrel to a first dose of a radiation to generate a first plurality of acid molecules within the first mandrel;
exposing the second mandrel to a second dose of the radiation to generate a second plurality of acid molecules within the second mandrel, wherein the first dose of the radiation is different from the second dose of the radiation;
baking the substrate to:
diffuse a portion of the first plurality of acid molecules into a first portion of the crosslinked overcoat layer to a first depth;
diffuse a portion of the second plurality of acid molecules into a second portion of the crosslinked overcoat layer to a second depth, wherein the second depth is different from the first depth;
induce a de-crosslinking reaction within the first portion of the crosslinked overcoat layer to form a first de-crosslinked region, wherein the first de-crosslinked region extends along a top and sidewalls of the first mandrel; and
induce a decrosslinking reaction within the second portion of the crosslinked overcoat layer to form a second de-crosslinked region, wherein the second de-crosslinked region extends along a top and sidewalls of the second mandrel, and wherein an unmodified region of the crosslinked overcoat layer interposed between the first de-crosslinked region and the second de-crosslinked region forms a third mandrel; and
selectively removing the first de-crosslinked region and the second de-crosslinked region, wherein the first mandrel, the second mandrel, and the third mandrel form a mandrel pattern on the substrate.

16. The method of claim 15, wherein a width of the first de-crosslinked region is different from a width of the second de-crosslinked region.

17. The method of claim 15, wherein a width of the first mandrel is different from a width of the third mandrel.

18. The method of claim 15, wherein a height of the first mandrel is different from a height of the third mandrel.

19. The method of claim 15, wherein the third mandrel comprises an overhang region.

20. The method of claim 15, wherein the overcoat layer has a first thickness over a top surface the first mandrel and a top surface of the second mandrel, and wherein the first thickness is less than a lesser of the first depth and the second depth.
